(19) United States
(12) Patent Application Publication
(10) Pub. No.: US 2021/0349387 A1
(43) Pub. Date: Nov. 11, 2021

(54) REFLECTIVE MASK BLANK, REFLECTIVE MASK, AND PROCESS FOR PRODUCING REFLECTIVE MASK BLANK

(71) Applicant: AGC Inc., Tokyo (JP)

(72) Inventors: Hiroyoshi TANABE, Tokyo (JP); Takahira MIYAGI, Tokyo (JP)

(73) Assignee: AGC Inc., Tokyo (JP)

(21) Appl. No.: 17/380,641

(22) Filed: Jul. 20, 2021

Related U.S. Application Data
(63) Continuation of application No. PCT/JP2020/001316, filed on Jan. 16, 2020.

(30) Foreign Application Priority Data
Jan. 21, 2019 (JP) 2019-007681

(51) Int. Cl. G03F 1/24; G03F 1/52

(52) U.S. Cl. CPC G03F 1/24; G03F 1/52

(57) ABSTRACT

A reflective mask blank includes a substrate and, disposed on or above the substrate in the following order from the substrate side, a reflective layer, a protective layer, and an absorbent layer. The reflective layer is a multilayered reflective film includes a plurality of cycles, each cycle including a high-refractive-index layer and a low-refractive-index layer. The reflective layer includes one phase inversion layer which is either the high-refractive-index layer or the low-refractive-index layer each having a film thickness increased by Δd ([unit: nm]). The increase in film thickness Δd [unit: nm] of the phase inversion layer satisfies a relationship: (¼+m/2)×13.53−1.0≤Δd≤(¼+m/2)×13.53+1.0. The reflective layer and the absorbent layer satisfy a relationship:

T_{abs}+80 tanh(0.037N_{ML})−1.6 exp(−0.08Nₜₒₚ)(N_{ML}−Nₜₒₚ)²<140.

### CROSS-REFERENCE TO RELATED APPLICATIONS

This is a bypass continuation of International Patent Application No. PCT/JP2020/001316, filed on Jan. 16, 2020, which claims priority to Japanese Patent Application No. 2019-007681, filed on Jan. 21, 2019. The contents of these applications are hereby incorporated by reference in their entireties.

### TECHNICAL FIELD

The present invention relates to a reflective mask blank, a reflective mask, and a process for producing the reflective mask blank.

### BACKGROUND ART

Nowadays, with the progress of microfabrication of integrated circuits for constituting semiconductor devices, extreme ultraviolet (hereinafter referred to as “EUV”) lithography is being investigated as an exposure method which replaces the conventional exposure technique employing visible light or ultraviolet light (wavelengths, 365-193 nm).

In EUV lithography, EUV light is used as a light source for exposure. The term “EUV light” means light having a wavelength in the soft X-ray region or vacuum ultraviolet region, and EUV light specifically is light having a wavelength of about 0.2-100 nm. For example, EUV light having a wavelength λ of about 13.5 nm is used in EUV lithography.

EUV light is apt to be absorbed by many substances and, hence, the dioptric systems used in conventional exposure techniques cannot be used therewith. Because of this, a catoptric system including a reflective mask, a mirror, etc. is used in EUV lithography. In EUV lithography, a reflective mask is used as a mask for transfer.

In a reflective mask, a reflective layer which reflects EUV light is formed on a substrate, and an absorbent layer absorbing the EUV light is pattern-wise formed on the reflective layer. The reflective mask is obtained from a reflective mask blank, as a precursor, configured by superposing a reflective layer and an absorbent layer in this order on a substrate, by partly removing the absorbent layer to form a given pattern.

Widely used as the reflective layer is a multilayered reflective film formed by cyclically superposing a plurality of high-refractive-index layers and a plurality of low-refractive-index layers. A multilayered reflective film in normal use is one formed by configuring an alternating multilayer film by superposing about 40 cycles each composed of an Mo layer, which constitutes a high-refractive-index layer, and an Si layer, which constitutes a low-refractive-index layer. The film thicknesses of the Mo layer and Si layer have been set at approximately λ/4 so that the light reflected by the two layers is mutually intensified. As the absorbent layer, a TaN film having a film thickness of about 60 nm is, for example, used.

EUV light which has entered such reflective mask is absorbed by the absorbent layer and reflected by the multilayered reflective film. The reflected EUV light is made to form an image on the surface of an exposure material (wafer coated with a resist) by a projecting optical system. Thus, the pattern of the absorbent layer, namely, a mask pattern, is transferred to the surface of the exposure material.

The projecting optical system has a magnification of ¼. In the case where a resist pattern having a line width of 20 nm or less is to be obtained on the wafer, the mask pattern needs to have a line width of 80 nm or less. Because of this, in the EUV mask, the film thickness of the absorbent layer is approximately equal to the line width of the mask pattern.

In EUV lithography, EUV light usually enters a reflective mask from a direction inclined at about 6°. Since the film thickness of the absorbent layer is approximately equal to the line width of the mask pattern, the three-dimensional structure of the pattern of the absorbent layer exerts various influences on the mask-pattern image projected on the wafer. These influences are called mask 3D effects.

For example, there is an effect called an H-V bias. Although EUV light obliquely enters the mask, the optical path is obstructed by the absorbent layer in H (horizontal) lines, which are a portion of the mask pattern that is perpendicular to the incidence plane, to cast a shadow. Meanwhile, V (vertical) lines, which are a portion of the mask pattern that is parallel with the incidence plane, cast no shadow. Because of this, the images of the H lines and V lines projected on the wafer differ in line width, and this difference is transferred to the resist pattern. This is called an H-V bias.

Another mask 3D effect is a telecentricity error. In the case of the H lines, the plus-first-order diffracted light and the minus-first-order diffracted light differ in intensity due to the inclined incidence. In this case, if the position of the wafer shifts upward or downward from the focal plane, the position of the image undesirably shifts in a horizontal direction. This is called a telecentricity error. In the case of V lines, the plus-first-order diffracted light and the minus-first-order diffracted light have the same intensity to cause no telecentricity error.

Since fidelity between the mask pattern and the image thereof projected on a wafer is impaired by the mask 3D effects, it is desirable that the mask 3D effects are as low as possible. A most straightforward means for reducing the mask 3D effects is to thin the absorbent layer, and this method is described, for example, in Non-Patent Document 1.

Among causes of the mask 3D effects, there is an influence of the multilayered reflective film, besides the absorbent layer. In the case of the multilayered reflective film, light reflection occurs not on the surface of the multilayered reflective film but inside the multilayered reflective film. In the case where a reflection plane lies inside the multilayered reflective film, this increases the effective film thickness of the absorbent layer. In this case, thinning the absorbent layer is insufficient in reducing the mask 3D effects.

Non-Patent Document 2 indicates a method for reducing the telecentricity error by increasing, by about 3% each, the thicknesses of Mo layers and Si layers which constitute a multilayered reflective film. This method, however, has a dependence on pattern pitch and has not succeeded in reducing the telecentricity error in all patterns differing in pitch.

Although the present invention is intended to reduce the mask 3D effects, it has been reported in documents that a specific effect is obtained by configuring multilayered reflective films different from ordinary ones.

Patent Document 1 describes a multilayered reflective film divided into an overlying multilayer film and an underlying multilayer film which differ from each other in cycle. By thus configuring a multilayered reflective film, a reflective mask emitting intense reflected light over a wide angle can be obtained.

Patent Document 2 describes a multilayered reflective film divided into an overlying multilayer film, an underlying multilayer film, and an interlayer, the interlayer having a thickness of m×λ/2 (m is a natural number). By thus configuring a multilayered reflective film, a reflective mask blank having few defects can be obtained in which light reflected by the underlying multilayer film and light reflected by the overlying multilayer film are mutually intensified without lowering the reflectance.

Patent Document 3 proposes various multilayer film configurations for the purpose of reducing the incidence-angle dependence of reflectance.

Patent Documents 1 to 3 neither mention nor suggest a reduction in mask 3D effect. Patent Document 3 describes a multilayered reflective film which includes no absorbent layer and hence does not produce a mask 3D effect.

### CITATION LIST

### Non-Patent Literature

Non-Patent Document 1: E. v. Setten et al., Proc. SPIE, Vol. 10450, 104500 W (2017)
Non-Patent Document 2: J. T. Neumann et al., Proc. SPIE, Vol. 8522, 852211 (2012)

### Patent Literature

Patent Document 1: JP-A-2007-134464
Patent Document 2: Japanese Patent No. 4666365
Patent Document 3: Japanese Patent No. 4466566

### SUMMARY OF THE INVENTION

### Technical Problem

An object of the present invention is to provide a reflective mask blank capable of reducing mask 3D effects and a reflective mask.

### Solution to the Problem

The present inventors diligently made investigations in order to accomplish the object and, as a result, have discovered that mask 3D effects can be reduced by configuring a multilayered reflective film in which one layer is a phase inversion layer. Namely, any one of the high-refractive-index layers and low-refractive-index layers which constitute the multilayered reflective film is made to function as a phase inversion layer having an increased film thickness. By disposing the phase inversion layer, light reflected by the upper multilayer film and light reflected by the lower multilayer film are caused to undergo interference so as to attenuate each other. Thus, a reduction in mask 3D effect can be attained.

For causing the destructive interference, the film thickness of the phase inversion layer is made larger by about (¼+m/2)×λ, than that of the high-refractive-index and low-refractive-index layers constituting the multilayered reflective film. Symbol m is an integer of 0 or larger.

The reason why the mask 3D effects are reduced by the present invention are explained using a ray-tracing model. In FIG. 2 are shown paths of reflected light within a multilayered reflective film. The multilayered reflective film of FIG. 2 has been configured by superposing only two cycles, each cycle (Mo/Si) being composed of an Mo layer constituting a high-refractive-index layer and Si constituting a low-refractive-index layer. However, actual blanks include, for example, 40 cycles of superposed layers. Meanwhile, the Si layer and the Mo layer each have an optimal film thickness which depends on the refractive index. However, since the refractive indexes of the two layers are close to 1, the film thicknesses of the two layers have both been set at λ/4 for simplicity.

In FIG. 2, r₀ represents the amplitude of light reflected by the surface of the multilayered reflective film. Reflected light passes through various paths in the multilayered reflective film and components thereof are classified according to positions in the surface where the reflected light comes out. Reflected light rᵢ comes out at a position shifted from the incidence position in a horizontal direction by i×λ/2×sin θ (usually, θ is 6 degrees). In this case, the overall amplitude r of the reflected light is expressed by the following expression (1).

$$\begin{matrix}[ Math . 1 ] \\ r = {\sum }_{i = 0}^{∞} {r}_{i}\end{matrix} \qquad ( 1 )$$

The reflectance is calculated with the following expression (2).

Reflectance=|r|² (2)

In the case where a reflected-light amplitude rᵢ is viewed from outside the multilayered reflective film, the light seems to have been reflected by the i-th layer from the surface. The depth of the reflection plane is i×λ/4. Then, the reflection plane for the overall amplitude is calculated by averaging reflection planes for reflected-light amplitudes rᵢ using the following expression (3).

$$\begin{matrix}[ Math . 2 ] \\ Reflection plane = {\sum }_{i = 0}^{∞} i \times {r}_{i} / r \times λ / 4\end{matrix} \qquad ( 3 )$$

Specific calculation examples are shown in FIG. 3, FIG. 4A and FIG. 4B. The refractive index and absorption coefficient of Si were regarded as 0.999 and 0.001826, respectively, and the refractive index and absorption coefficient of Mo were regarded as 0.9238 and 0.006435, respectively.

Reflected-light amplitude rᵢ depends on the total number of layers N_{ML} of the multilayered reflective film. FIG. 3 shows the results of a calculation of reflected-light amplitude in the case where N_{ML} is 80 (40 cycles of Mo/Si). Since the incident light reaches the substrate when i is a value corresponding to the total number of layers N_{ML} of 80, the rᵢ is discontinuous.

FIG. 4A shows an example of a calculation of reflectance. It can be seen from FIG. 4A that the reflectance gradually increases as the number of cycles increases, and approaches a maximum value around 0.7. In the case where a multilayered reflective film is configured so that the total number of layers N_{ML} is 80, a reflectance sufficiently close to the maximum value is obtained.

FIG. 4B shows an example of a calculation of the reflection plane. It can be seen from FIG. 4B that the depth of the reflection plane also gradually increases as the number of cycles increases. In multilayered reflective films in which the total number of layers N_{ML} is about 80, the depths of the reflection plane are about 80 nm.

In the present invention, a multilayered reflective film is configured so as to include a phase inversion layer therein to cause destructive interference between light reflected by the upper multilayer film, which overlies the phase inversion layer, and light reflected by the lower multilayer film, which underlies the phase inversion layer. A specific example thereof is shown in FIG. 5, in which the number of layers of the upper multilayer film 12c is expressed by Nₜₒₚ, the underlying Si film is the phase inversion layer 12b, and the film thickness thereof has been increased by λ/4 to be λ/2. By thus configuring the multilayered reflective film, the light reflected by the lower multilayer film 12a and the light reflected by the upper multilayer film 12c attenuate each other.

FIG. 6 shows the results of a calculation of reflected-light amplitude rᵢ for a multilayered reflective film having the configuration shown in FIG. 5. The total number of layers N_{ML} of the multilayered reflective film is 80, and the number of layers Nₜₒₚ of the upper multilayer film is 50. It can be seen from FIG. 6 that the reflected-light amplitude rᵢ is inverted at the point where i is 50.

FIG. 7 shows calculations of reflectance and the reflection plane in which the number of layers Nₜₒₚ of an upper multilayer film is fixed to 40, 50, or 60 and the total number of layers N_{ML} is changed. FIG. 7A shows the results of the calculations of reflectance. It can be seen from FIG. 7A that after the N_{ML} exceeded the Nₜₒₚ, the reflectance gradually decreased due to attenuation by the lower multilayer film. FIG. 7B shows the results of the calculations of the reflection plane. It can be seen from FIG. 7B that after the N_{ML}, exceeded the Nₜₒₚ, the depth of the reflection plane rapidly became small. Consequently, it is possible to considerably reduce the depth to the reflection plane while minimizing the decrease in reflectance.

The reason why the position of the reflection plane rapidly shallows can be understood from expression (3) given above. In expression (3), the contribution of the reflected-light amplitude rᵢ to the reflection plane has been enhanced i times. Because of this, the reflectance of a layer lying in a deep position contributes more than the reflectance of a layer lying in a shallow position. When i is larger than Nₜₒₚ, phase inversion occurs and the reflected-light amplitude rᵢ has negative values. Because of this, the position of the reflection plane rapidly shallows after the total number of layers N_{ML} of the multilayered reflective film exceeds the Nₜₒₚ.

It can be seen from FIG. 7B that the reflection plane is a function of both the total number of layers N_{ML} of the multilayered reflective film and the Nₜₒₚ of the upper multilayer film. In the case where the depth to the reflection plane in the multilayered reflective film is expressed by D_{ML}(N_{ML}, Nₜₒₚ) [unit: nm], the calculation results shown in FIG. 7B are approximated by the following expression (4).

D_{ML}(N_{ML},Nₜₒₚ)=80 tanh(0.037N_{ML})−1.6 exp(−0.08Nₜₒₚ)(N_{ML}−Nₜₒₚ)² (4)

In the case where the film thickness of the absorbent layer is expressed by T_{abs} [unit: nm], the effective thickness of the absorbent layer determined while taking account of the depth to the reflection plane is T_{abs}+D_{ML}(N_{ML}, Nₜₒₚ). Since the current TaN absorbent layers have film thicknesses of about 60 nm and conventional multilayered reflective films have reflection-plane depths of about 80 nm, the following expression (5) needs to be satisfied for reducing mask 3D effects.

T_{abs}+D_{ML}(N_{ML},Nₜₒₚ)<140 (5)

It is more preferable that the following expression (6) is satisfied.

T_{abs}+D_{ML}(N_{ML},Nₜₒₚ)<120 (6)

The example explained above was the case where an Si film was used as a phase inversion layer having a film thickness increased by λ/4 to be λ/2. However, the same effect is produced also in the case where an Mo film is used as a phase inversion layer having a film thickness increased by λ/4 to be λ/2.

As described above, a reflective mask blank which includes a multilayered reflective film including a phase inversion layer disposed therein and which includes an absorbent layer and the reflective layer that satisfy expression (5) or (6) is obtained. By using a reflective mask obtained from this reflective mask blank, mask 3D effects can be reduced.

The present invention provides A reflective mask blank including a substrate and, disposed on or above the substrate in the following order from the substrate side, a reflective layer for reflecting EUV light, a protective layer, and an absorbent layer for absorbing EUV light,

wherein the reflective layer is a multilayered reflective film including a plurality of cycles, each cycle including a high-refractive-index layer and a low-refractive-index layer,

wherein the reflective layer comprises one phase inversion layer which is either the high-refractive-index layer or the low-refractive-index layer each having a film thickness increased by Δd ([unit: nm]),

wherein the increase in film thickness Δd [unit: nm] of the phase inversion layer satisfies a relationship:

(¼+m/2)×13.53−1.0≤Δd≤(¼+m/2)×13.53+1.0

where m is an integer of 0 or larger, and

wherein the reflective layer and the absorbent layer satisfy a relationship:

T_{abs}+80 tanh(0.037N_{ML})−1.6 exp(−0.08Nₜₒₚ)(N_{ML}−Nₜₒₚ)²<140

where N_{ML} is the total number of layers of the reflective layer, Nₜₒₚ is the number of layers of an upper multilayer film that is a portion of the reflective layer which overlies the phase inversion layer, and T_{abs} [unit: nm] is a film thickness of the absorbent layer

The present invention further provides a reflective mask obtained by forming a pattern in the absorbent layer of the reflective mask blank of the present invention.

The present invention furthermore provides a process for producing a reflective mask blank including a substrate and, disposed on or above the substrate in the following order from the substrate side, a reflective layer for reflecting EUV light, a protective layer, and an absorbent layer for absorbing EUV light,

the reflective layer being a multilayered reflective film comprising a plurality of cycles, each cycle being composed of a high-refractive-index layer and a low-refractive-index layer,

the reflective layer including a lower multilayer film, a phase inversion layer which is either the high-refractive-index layer or the low-refractive-index layer each having an increased film thickness, and an upper multilayer film which have been superposed in this order from the substrate side, the process including:

forming the lower multilayer film on the substrate;

forming the phase inversion layer on the lower multilayer film;

forming the upper multilayer film on the phase inversion layer;

forming the protective film on the upper multilayer film, and

forming the absorbent layer on the protective layer.

### Advantageous Effect of Invention

The reflective mask blank of the present invention and the reflective mask obtained from the reflective mask blank can reduce mask 3D effects.

### BRIEF DESCRIPTION OF DRAWINGS

FIG. 1 is a diagrammatic cross-sectional view of one example of the configuration of a reflective mask blank according to an embodiment of the present invention.

FIG. 2 is a diagram showing paths of reflected light in a multilayered reflective film.

FIG. 3 is a diagram showing an example of a calculation of reflected-light amplitude rᵢ.

FIG. 4A is a diagram showing an example of a calculation of reflectance.

FIG. 4B is a diagram showing an example of a calculation of reflection-plane depth.

FIG. 5 is a diagram showing one example of the configuration of a multilayered reflective film in the present invention.

FIG. 6 is a diagram showing the results of a calculation of the reflected-light amplitude rᵢ of the multilayered reflective film of FIG. 5.

FIG. 7A is a diagram showing examples of calculations of reflectance.

FIG. 7B is a diagram showing examples of calculations of reflection-plane depth.

FIG. 8 is a diagrammatic cross-sectional view of one example of the configuration of another reflective mask blank according to an embodiment of the present invention.

FIG. 9 is a diagrammatic cross-sectional view of one example of the configuration of still another reflective mask blank according to an embodiment of the present invention.

FIG. 10 is a flowchart illustrating one example of a process for producing a reflective mask blank.

FIG. 11 is a diagrammatic cross-sectional view showing one example of the configuration of a reflective mask.

FIG. 12 is views illustrating steps for producing the reflective mask.

FIG. 13 is a diagrammatic cross-sectional view of the reflective mask blank of Example 1.

FIG. 14 is a diagram showing the results of calculations of reflectance performed in Examples 1 to 3.

FIG. 15 is a diagram showing the results of H-V bias simulations performed in Examples 1 to 4.

FIG. 16 is a diagram showing the results of telecentricity error simulations performed in Examples 1 to 4.

FIG. 17 is a diagram showing the results of calculations of reflectance performed in Examples 2, 5, and 6.

FIG. 18 is a diagram showing the results of H-V bias simulations performed in Examples 2 and 5 to 7.

FIG. 19 is a diagram showing the results of telecentricity error simulations performed in Examples 2 and 5 to 7.

### DESCRIPTION OF EMBODIMENTS

Embodiments of the present invention are described below in detail.

### <Reflective Mask Blank>

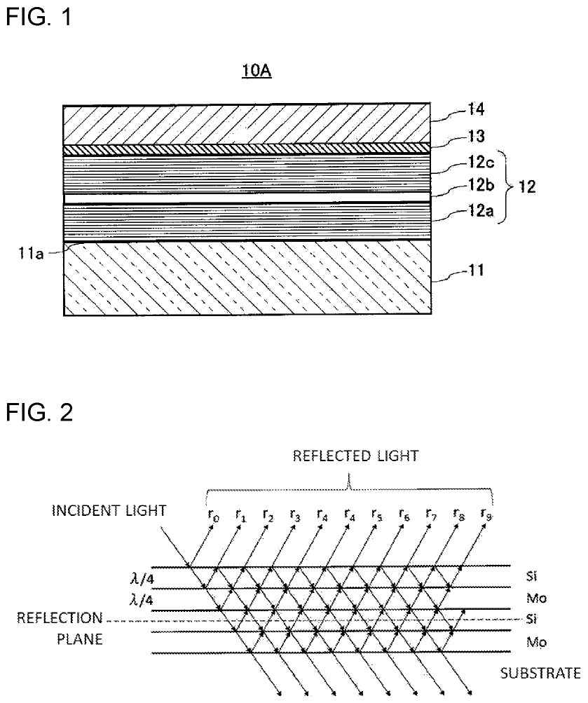

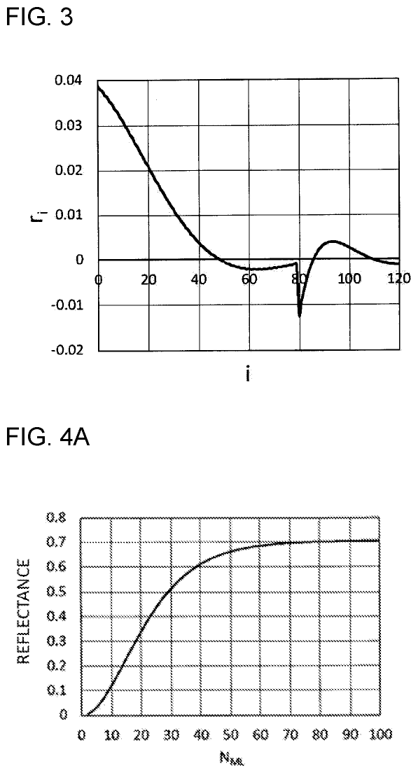

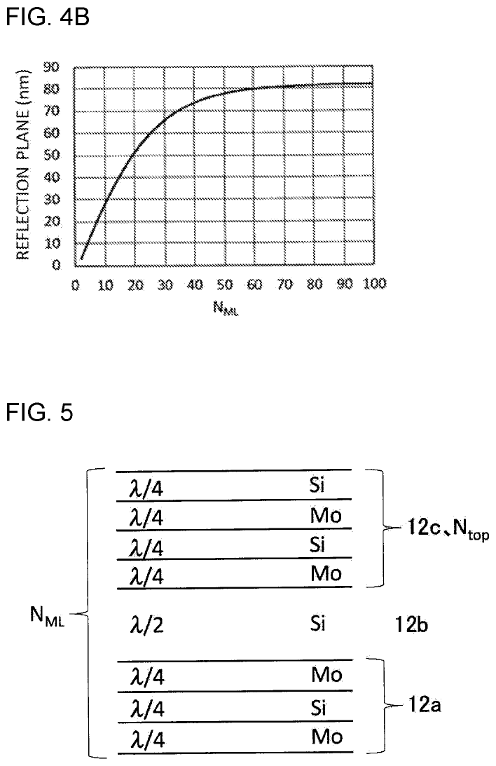

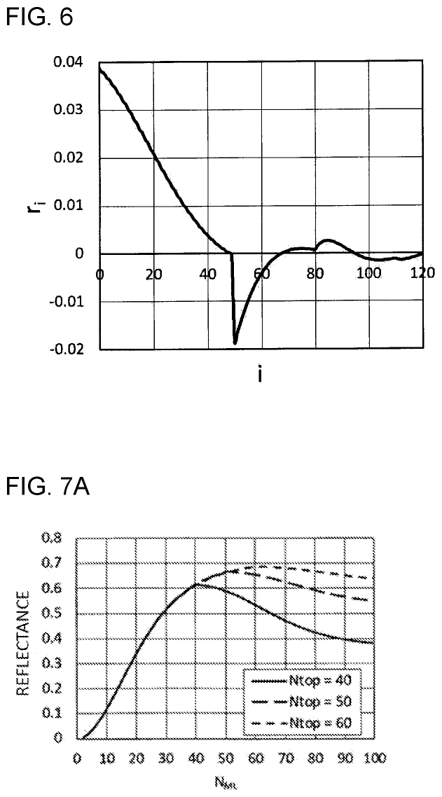

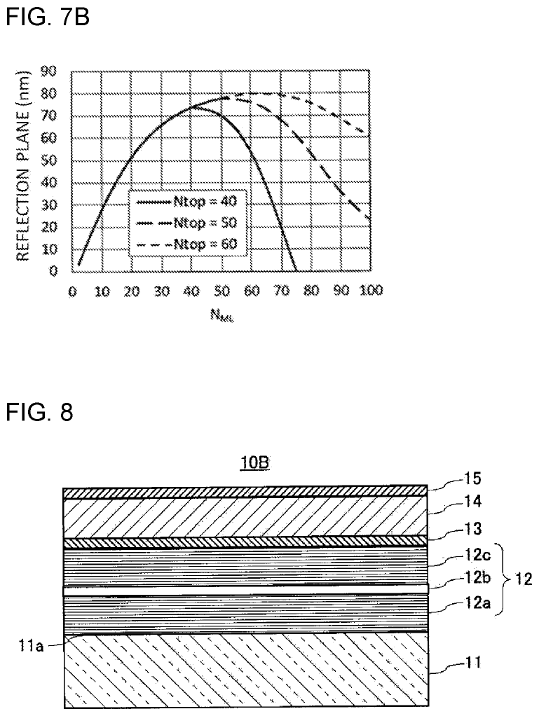

A reflective mask blank according to an embodiment of the present invention is explained. FIG. 1 is a diagrammatic cross-sectional view of an example of the configuration of a reflective mask blank according to an embodiment of the present invention. As FIG. 1 shows, the reflective mask blank 10A has been configured by superposing a reflective layer 12, a protective layer 13, and an absorbent layer 14 in this order on a substrate 11.

### (Substrate)

It is preferable that the substrate 11 has a low coefficient of thermal expansion. The substrate 11 having a lower coefficient of thermal expansion is more effective in inhibiting a pattern to be formed in the absorbent layer 14 from being deformed by heat during exposure to EUV light. Specifically, the coefficient of thermal expansion of the substrate 11 at 20° C. is preferably 0±1.0×10⁻⁷° C., more preferably 0±0.3×10⁻⁷/° C.

As a material having a low coefficient of thermal expansion, an SiO₂—TiO₂ glass or the like can, for example, be used. The SiO₂—TiO₂ glass to be used is preferably silica glass including 90-95 mass % SiO₂ and 5-10 mass % TiO₂. In the case where the content of TiO₂ is 5-10 mass %, the coefficient of linear expansion at around room temperature is approximately zero and this glass dimensionally change little at around room temperature. The SiO₂—TiO₂ glass may contain minor components besides SiO₂ and TiO₂.

It is preferable that the first main surface 11a of the substrate 11, which is on the side where the reflective layer 12 is to be superposed, has high smoothness. The smoothness of the first main surface 11a can be determined with an atomic force microscope and be evaluated in terms of surface roughness. The surface roughness of the first main surface 11a is preferably 0.15 nm or less in terms of root-mean-square roughness Rq.

It is preferable that the first main surface 11a is processed so as to have a given flatness. This is for enabling the reflective mask blank to give a reflective mask having high pattern transfer accuracy and high positional accuracy. The substrate 11 has a flatness of preferably 100 nm or less, more preferably 50 nm or less, still more preferably 30 nm or less, in a given area (e.g., 132 mm×132 mm area) in the first main surface 11a.

It is preferable that the substrate 11 has resistance to cleaning liquids for use in, for example, cleaning the reflective mask blank, the reflective mask blank in which a pattern has been formed, or the reflective mask.

Furthermore, it is preferable that the substrate 11 has high rigidity, from the standpoint of preventing the substrate 11 from being deformed by the membrane stress of a film (e.g., the reflective layer 12) to be formed over the substrate 11. For example, the substrate 11 preferably has a Young's modulus as high as 65 GPa or above.

### (Reflective Layer)

The reflective layer 12 is configured by superposing a lower multilayer film 12a, a phase inversion layer 12b, and an upper multilayer film 12c in this order from the substrate 11 side.

The reflective layer 12 is a multilayered reflective film formed by cyclically superposing a plurality of layers including, as main components, elements which differ in EUV-light refractive index. The term “main component” herein means a component which is the highest in content among the elements contained in each layer. The multilayered reflective film may be one formed by superposing a plurality of cycles, each cycle being a structure formed by superposing a high-refractive-index layer and a low-refractive-index layer in this order from the substrate 11 side, or may be one formed by superposing a plurality of cycles, each cycle being a structure formed by superposing a low-refractive-index layer and a high-refractive-index layer in this order.

As the high-refractive-index layers, layers including Si can be used. As a material including Si, use can be made of elemental Si or an Si compound including Si and one or more elements selected from the group consisting of B, C, N, and O. By using high-refractive-index layers including Si, a reflective mask having an excellent EUV-light reflectance is obtained. As the low-refractive-index layers, use can be made of at least one metal selected from the group consisting of Mo and Ru or an alloy of these. In this embodiment, it is preferable that the low-refractive-index layers are layers including Mo and the high-refractive-index layers are layers including Si. In this case, the reflective layer 12 may be configured so that the uppermost layer thereof is a high-refractive-index layer (layer including Si). Thus, a silicon oxide layer including Si and O is formed between the uppermost layer (Si layer) and the protective layer 13 to improve the cleaning resistance of the reflective mask.

The lower multilayer film 12a and the upper multilayer film 12c each include a plurality of cycles each including a high-refractive-index layer and a low-refractive-index layer. However, the high-refractive-index layers need not always have the same film thickness, and the low-refractive-index layers need not always have the same film thickness. In the case where the low-refractive-index layers are Mo layers and the high-refractive-index layers are Si layers, it is preferable that the cycle length, which is defined as the total film thickness of the Mo layer and Si layer in each cycle, is in the range of 6.5-7.5 nm and that ΓMo ([thickness of Mo layer]/[cycle length]) is in the range of 0.25-0.7. It is especially desirable that the cycle length is 6.9-7.1 nm and ΓMo is 0.35-0.5. The term “thickness of Mo layer” herein means the total thickness of the Mo layers included in the reflective layer.

A mixture layer appears at the interface between a low-refractive-index layer and a high-refractive-index layer. For example, an MoSi layer appears at the interface between an Mo layer and an Si layer. A thin buffer layer (e.g., a buffer layer having a film thickness of 1 nm or less, preferably a buffer layer having a film thickness of 0.1 nm or more and 1 nm or less) may be disposed in order to prevent the appearance of the mixture layer. A preferred material for the buffer layer is B₄C. For example, by interposing a B₄C layer of about 0.5 nm between an Mo layer and an Si layer, the appearance of an MoSi layer can be prevented. In this case, the total film thickness of the Mo layer, B₄C layer, and Si layer is the cycle length.

The phase inversion layer 12b serves to cause light reflected by the lower multilayer film 12a and light reflected by the upper multilayer film 12c to attenuate each other. The phase inversion layer may be either a low-refractive-index layer or a high-refractive-index layer. For phase inversion, the following expression (7) is satisfied, in which Δd [unit: nm] is an increase in the film thickness of the phase inversion layer.

(¼+m/2)×13.53−1.0≤Δd≤(¼+m/2)×13.53+1.0 (7)

In expression (7), m is an integer of 0 or larger.

More preferably, the following expression (8) is satisfied.

(¼+m/2)×13.53−0.5≤Δd≤(¼+m/2)×13.53+0.5 (8)

In particular, when m is 0, expression (8) is as follows.

2.9≤Δd≤3.9 (9)

The upper multilayer film 12c has been configured by superposing high-refractive-index layers and low-refractive-index layers, and there are a lower limit and an upper limit on the number of layers Nₜₒₚ thereof. In case where Nₜₒₚ is smaller than 20, this undesirably results in a considerably reduced reflectance of 40% or less. Meanwhile, in case where Nₒₚ is larger than 100, the light which reaches the lower multilayer film 12a has considerably weakened, resulting in almost no effect of attenuation between light reflected by the upper multilayer film 12c and light reflected by the lower multilayer film 12a.

Consequently, Nₜₒₚ is preferably 20≤Nₜₒₚ≤100, more preferably 40≤Nₜₒₚ≤60.

Each of the layers which are to constitute the reflective layer 12 can be deposited in a desired thickness using any of known deposition methods such as magnetron sputtering and ion-beam sputtering. For example, in the case of using ion-beam sputtering to produce the reflective layer 12, ion particles are supplied from an ion source to a target of a high-refractive-index material and a target of a low-refractive-index material to thereby conduct deposition.

### (Protective Layer)

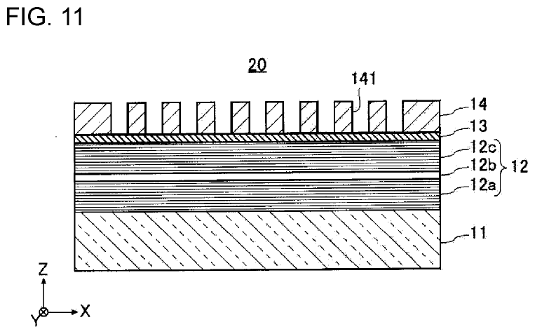

The protective layer 13 protects the reflective layer 12 so that In the case where the absorbent layer 14 is etched (usually dry-etched) to form an absorber pattern 141 in the absorbent layer 14 in producing the reflective mask 20 shown in FIG. 11, the surface of the reflective layer 12 is inhibited from being damaged by the etching. In addition, in the case where the reflective mask blank which has undergone the etching is cleaned by removing a resist layer 18 remaining thereon using a cleaning liquid, the protective layer 13 protects the reflective layer 12 from the cleaning liquid. Because of this, the reflective mask 20 thus obtained has a satisfactory EUV-light reflectance.

Although FIG. 1 shows an embodiment including one protective layer 13, the reflective mask blank may include a plurality of protective layers 13.

As a material for forming the protective layer 13, a substance which is less apt to be damaged by the etching of the absorbent layer 14 is selected. Examples of substances which satisfy this requirement include: Ru-based materials such as metallic Ru, Ru alloys including Ru and one or more metals selected from the group consisting of B, Si, Ti, Nb, Mo, Zr, Y, La, Co, and Re, and nitrides which are these Ru alloys containing nitrogen; Cr, Al, Ta, and nitrides including any of these metals and nitrogen; and SiO₂, Si₃N₄, Al₂O₃, and mixtures of these. Preferred of these are metallic Ru, Ru alloys, CrN, and SiO₂. Metallic Ru and Ru alloys are especially preferred because these materials are less apt to be etched with oxygen-free gases and can function as an etching stopper during processing for producing a reflective mask.

In the case where the protective layer 13 is constituted of an Ru alloy, it is preferable that the Ru content in the Ru alloy is 95 at % or higher but less than 100 at %. In the case where the reflective layer 12 is a multilayered reflective film including a plurality of cycles which each are a structure formed by superposing an Mo layer as a high-refractive-index layer and an Si layer as a low-refractive-index layer and when the Ru content is within that range, then this protective layer 13 can inhibit Si from diffusing from the Si layer which is the uppermost layer of the reflective layer 12 into the protective layer 13. The protective layer 13 further functions as an etching stopper during etching of the absorbent layer 14, while maintaining a sufficient EUV-light reflectance. In addition, the protective layer 13 can impart cleaning resistance to the reflective mask and can prevent the reflective layer 12 from deteriorating with the lapse of time.

The film thickness of the protective layer 13 is not particularly limited so long as the protective layer 13 can perform its functions. From the standpoint of maintaining the reflectance of EUV light reflected by the reflective layer 12, the film thickness of the protective layer 13 is preferably 1 to 8 nm, more preferably 1.5 to 6 nm, still more preferably 2 to 5 nm.

As a method for forming the protective layer 13, use can be made of a known film-forming method such as sputtering or ion-beam sputtering.

### (Absorbent Layer)

In order for the absorbent layer 14 to be usable for producing reflective masks for EUV lithography, the absorbent layer 14 needs to have properties such as having a high EUV-light absorption coefficient, being capable of easily etched, and having high resistance to cleaning with cleaning liquids.

The absorbent layer 14 absorbs EUV light and has an extremely low EUV-light reflectance. Specifically, in the case where the surface of the absorbent layer 14 is irradiated with EUV light, the maximum value of the reflectance of the EUV light having a wavelength of around 13.53 nm is preferably 2% or less, more preferably 1% or less. The absorbent layer 14 hence needs to have a high coefficient of EUV-light absorption coefficient.

The absorbent layer 14 is processed by etching, e.g., dry etching with a Cl-based gas or a CF-based gas. The absorbent layer 14 hence needs to be easily etched.

In producing the reflective mask 20 which is described later, the absorbent layer 14 is exposed to a cleaning liquid when the resist pattern 181 remaining on the reflective mask blank after the etching is removed with the cleaning liquid. As this cleaning liquid, use is made of sulfuric acid/hydrogen peroxide mixture (SPM), sulfuric acid, ammonia, ammonia/hydrogen peroxide mixture (APM), OH-radical cleaning water, ozonized water, etc.

As a material for constituting the absorbent layer 14, a Ta-based material is frequently used. Adding N, O, or B to Ta improves the resistance to oxidation, thereby attaining an improvement in long-term stability. In order to facilitate pattern-defect inspections to be performed after mask processing, an absorption layer having a two-layer structure, e.g., a structure composed of a TaN film and a TaON film superposed thereon, is often employed.

For forming an absorbent layer 14 having a reduced thickness, a material having a high EUV-light absorption coefficient is necessary. An alloy obtained by adding at least one metal selected from the group consisting of Sn, Co, and Ni to Ta has an increased absorption coefficient.

It is preferable that the crystalline state of the absorbent layer 14 is an amorphous. The absorbent layer 14 in this state can have excellent smoothness and flatness. The improved smoothness and flatness of the absorbent layer 14 enable the absorber pattern 141 to have reduced edge roughness and enhanced dimensional accuracy.

The absorbent layer 14 may be either a single-layer film or a multilayer film composed of a plurality of films. In the case where the absorbent layer 14 is a single-layer film, the number of steps for mask blank production can be reduced to improve the production efficiency. In the case where the absorbent layer 14 is a multilayer film, an upper-side layer of the absorbent layer 14 can be made usable as an antireflection film in inspecting the absorber pattern 141 using inspection light, by suitably setting the optical constants and film thickness of the upper-side layer. Thus, the inspection sensitivity in inspecting the absorber pattern can be improved.

The absorbent layer 14 can be formed using a known deposition method such as magnetron sputtering or ion-beam sputtering. For example, in the case of forming a TaN film as the absorbent layer 14 using magnetron sputtering, this absorbent layer 14 can be deposited by reactive sputtering in which a Ta target is used and a mixed gas composed of Ar gas and N₂ gas is used.

### (Other Layers)

The reflective mask blank of the present invention may include a hard mask layer 15 on the absorbent layer 14 like the reflective mask blank 10B shown in FIG. 8. It is preferable that the hard mask layer 15 includes at least one element selected from the group consisting of Cr and Si. As the hard mask layer 15, use is made of a material having high resistance to etching, such as, for example, a Cr-based film or an Si-based film. Specifically, use is made of a material having high resistance to dry etching with a Cl-based gas or a CF-based gas. Examples of the Cr-based film include Cr and materials obtained by adding O or N to Cr. Specific examples thereof include CrO, CrN, and CrON. Examples of the Si-based film include Si and materials obtained by adding one or more elements selected from the group consisting of O, N, C, and H to Si. Specific examples thereof include SiO₂, SiON, SiN, SiO, Si, SiC, SiCO, SiCN, and SiCON. Of these materials, the Si-based films are preferred because sidewall regression is less apt to occur in dry-etching the absorbent layer 14. The formation of the hard mask layer 15 on the absorbent layer 14 makes it possible to perform dry etching even in the case where the absorber pattern 141 has a reduced minimum line width. The formation thereof hence is effective in line-size reductions in the absorber pattern 141.

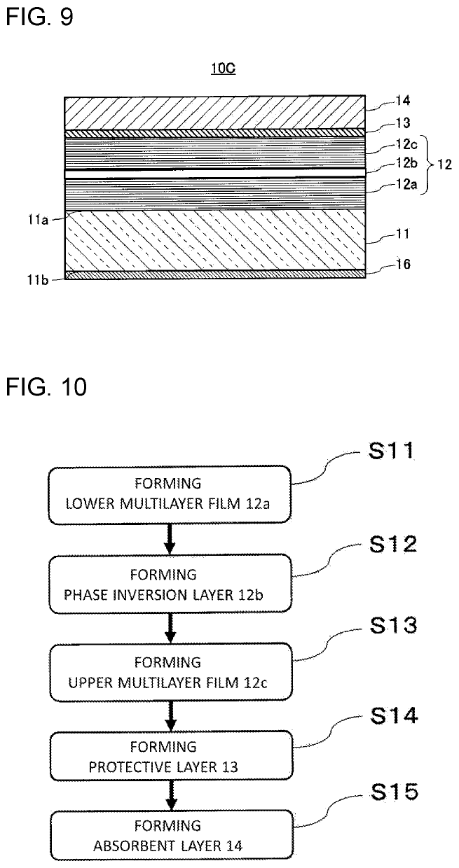

The reflective mask blank of the present invention may include a backside electroconductive layer 16 for electrostatic chucking disposed on the second main surface 11b of the substrate 11 which is on the reverse side from the surface where the reflective layer 12 is superposed, like the reflective mask blank 10C shown in FIG. 9. A property required of the backside electroconductive layer 16 is a low sheet resistance value. The sheet resistance value of the backside electroconductive layer 16 is, for example, 250Ω/□ or less, preferably 200Ω/□ or less.

As a material for constituting the backside electroconductive layer 16, use can be made, for example, of a metal such as Cr or Ta or an alloy or compound of either. As the compound including Cr, use can be made of a compound including Cr and one or more elements selected from the group consisting of B, N, O, and C. As the compound including Ta, use can be made of a compound including Ta and one or more elements selected from the group consisting of B, N, O, and C.

The film thickness of the backside electroconductive layer 16 is not particularly limited so long as this backside electroconductive layer 16 satisfies the function of electrostatic chucking. For example, the film thickness thereof is 10 to 400 nm. This backside electroconductive layer 16 can serve to perform stress regulation on the second main surface 11b side in the reflective mask blank 10C. That is, the backside electroconductive layer 16 can have stress balanced with the stress due to various layers formed on the first main surface 11a side, thereby regulating the reflective mask blank 10C so as to be flat.

As a method for forming the backside electroconductive layer 16, use can be made of a known deposition method such as magnetron sputtering or ion-beam sputtering.

For example, the backside electroconductive layer 16 can be formed on the second main surface 11b of the substrate 11 before the reflective layer 12 is formed.

### <Process for Producing Reflective Mask Blank>

A process for producing the reflective mask blank 10A shown in FIG. 1 is explained next. FIG. 10 is a flowchart showing one example of a process for producing the reflective mask blank 10A.

As shown in FIG. 10, a lower multilayer film 12a is formed on a substrate 11 (step of forming a lower multilayer film 12a: step S11). The lower multilayer film 12a is deposited in a desired film thickness on the substrate 11 using a known deposition method as shown above.

Subsequently, a phase inversion layer 12b is formed on the lower multilayer film 12a (step of forming a phase inversion layer 12b: step S12). The phase inversion layer 12b is deposited in a desired film thickness on the lower multilayer film 12a using a known deposition method as shown above.

Subsequently, an upper multilayer film 12c is formed on the phase inversion layer 12b (step of forming an upper multilayer film 12c: step S13). The upper multilayer film 12c is deposited in a desired film thickness on the phase inversion layer 12b using a known deposition method as shown above.

Subsequently, a protective layer 13 is formed on the upper multilayer film 12c (step of forming a protective layer 13: step S14). The protective layer 13 is deposited in a desired film thickness on the upper multilayer film 12c using a known deposition method.

Subsequently, an absorbent layer 14 is formed on the protective layer 13 (step of forming an absorbent layer 14: step S15). The absorbent layer 14 is deposited in a desired film thickness on the protective layer 13 using a known deposition method.

As a result, a reflective mask blank 10A such as that shown in FIG. 1 is obtained.

### <Reflective Mask>

Next, a reflective mask obtained from the reflective mask blank 10A shown in FIG. 1 is explained. FIG. 11 is a diagrammatic cross-sectional view showing one example of the configuration of a reflective mask. The reflective mask 20 shown in FIG. 11 is one obtained by forming a desired absorber pattern 141 in the absorbent layer 14 of the reflective mask blank 10A shown in FIG. 1.

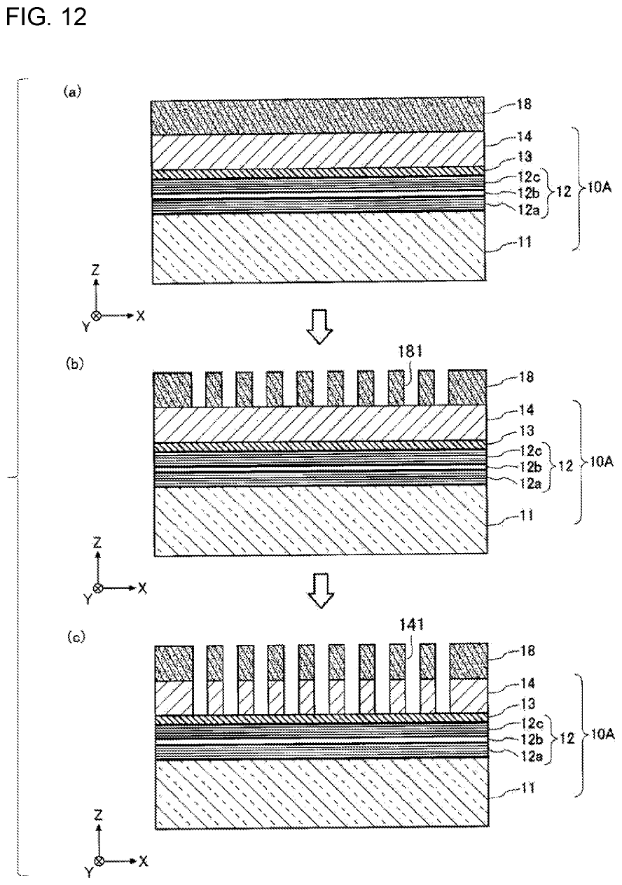

One example of processes for producing the reflective mask 20 is explained. FIG. 12 is views illustrating steps for producing the reflective mask 20. As the part (a) of FIG. 12 shows, a resist layer 18 is formed on the absorbent layer 14 of the reflective mask blank 10A shown in FIG. 1, which was described above.

Thereafter, the resist layer 18 is exposed to light in accordance with a desired pattern. After the exposure, the exposed areas of the resist layer 18 are developed, and this resist layer 18 is rinsed with pure water, thereby forming a given resist pattern 181 in the resist layer 18 as shown in the part (b) of FIG. 12.

Thereafter, the resist layer 18 having the resist pattern 181 formed therein is used as a mask to dry-etch the absorbent layer 14. Thus, an absorber pattern 141 corresponding to the resist pattern 181 is formed in the absorbent layer 14 as shown in the part (c) of FIG. 12. As an etching gas, use can be made of a fluorine-based gas such as CF₄ or CHF₃, a chlorine-based gas such as Cl₂, SiCl₄, or CHCl₃, a mixed gas including a chlorine-based gas and O₂, He, or Ar in a given proportion, or the like.

Thereafter, the resist layer 18 is removed with a resist remover liquid or the like to form a desired absorber pattern 141 in the absorbent layer 14. Thus, a reflective mask 20 in which the desired absorber pattern 141 has been formed in the absorbent layer 14 as shown in FIG. 11 can be obtained.

The obtained reflective mask 20 is irradiated with EUV light by an illuminating optical system of an exposure device. The EUV light which has entered the reflective mask 20 is reflected by the portions where the absorbent layer 14 is not present and is absorbed by the portions where the absorbent layer 14 is present. As a result, the reflected EUV light passes through a reductive-projection optical system of the exposure device and is caused to strike on an exposure material (e.g., a wafer of the like). Thus, the absorber pattern 141 of the absorbent layer 14 is transferred to the surface of the exposure material to form a circuit pattern in the surface of the exposure material.

### EXAMPLES

Examples 1, 5, and 7 are Comparative Examples, and Examples 2 to 4 and 6 are Examples according to the present invention.

### Example 1

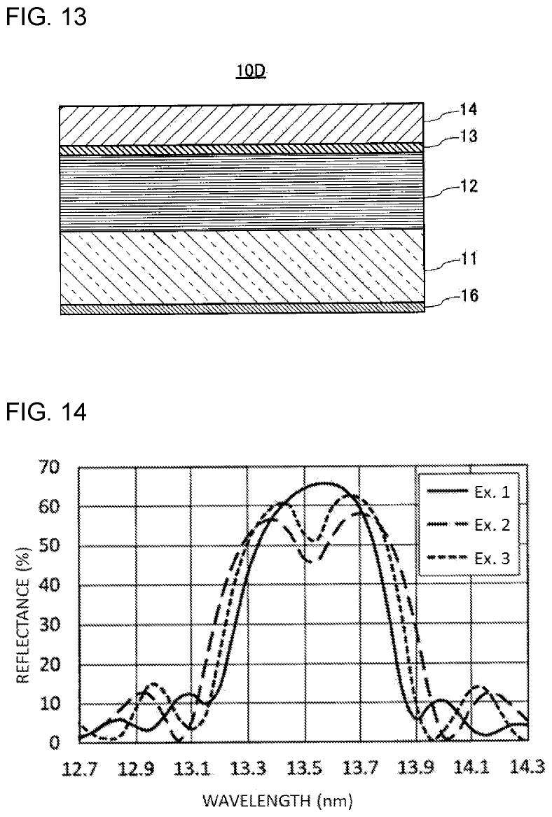

A reflective mask blank 10D is shown in FIG. 13. The reflective mask blank 10D includes a reflective layer 12 having no phase inversion layer 12b therein.

### (Production of Reflective Mask Blank)

As a substrate 11 for deposition, an SiO₂—TiO₂ glass substrate (outer shape, about 152-mm square; thickness, about 6.3 mm) was used. This glass substrate had a coefficient of thermal expansion of 0.02×10⁻⁷/° C. or less. The glass substrate was polished to make a surface thereof flat and have a surface roughness of 0.15 nm or less in terms of root-mean-square roughness Rq and a flatness of 100 nm or less. A Cr layer having a thickness of about 100 nm was deposited on the back surface of the glass substrate by magnetron sputtering, thereby forming a backside electroconductive layer 16 for electrostatic chucking. The Cr layer had a sheet resistance value of about 100 Ω/□.

After the deposition of the backside electroconductive layer 16 on the back surface of the substrate 11, an Si film and an Mo film were alternately deposited repeatedly over 40 cycles on the front surface of the substrate 11 by ion-beam sputtering. The film thickness of each Si film was about 4.0 nm and the film thickness of each Mo film was about 3.0 nm. Thus, a reflective layer 12 (multilayered reflective film) having an overall film thickness of about 280 nm ((4.0 nm of Si film)+(3.0 nm of Mo film)×40) was formed. Thereafter, an Ru layer (having a film thickness of about 2.5 nm) was deposited on the reflective layer 12 by ion-beam sputtering, thereby forming a protective layer 13.

Next, an absorbent layer 14 was deposited on the protective layer 13. The absorbent layer 14 had a two-layer structure composed of a TaN film and a TaON film functioning as an antireflection film. The TaN film was formed by magnetron sputtering. Ta was used as a sputtering target, and an Ar/N₂ mixed gas was used as a sputtering gas. The TaN film had a film thickness of 56 nm.

The TaON film also was deposited by magnetron sputtering. Ta was used as a sputtering target, and an Ar/O₂/N₂ mixed gas was used as a sputtering gas. The TaON film had a film thickness of 5 nm.

### (Reflectance and Mask 3D Effects)

Reflectances of the reflective mask blank 10D were calculated, and the results thereof are shown in FIG. 14. The reflectances had a maximum value of 66% at a wavelength of about 13.55 nm.

Mask 3D effects of the reflective mask blank 10D were investigated by simulations, in which the refractive index and absorption coefficient of TaN were regarded as 0.948 and 0.033, respectively, and the refractive index and absorption coefficient of TaON were regarded as 0.955 and 0.025, respectively.

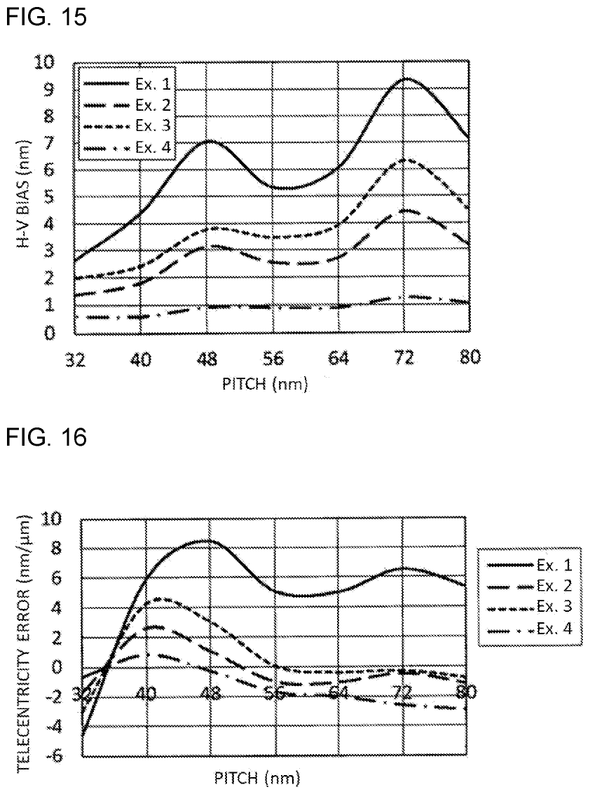

FIG. 15 shows the results of the simulation of H-V bias. Exposure was conducted by annular illumination under the conditions of a numerical aperture NA of 0.33 and a coherent factor σ of 0.5-0.7. Mask patterns having a space width of 64 nm (16 nm on wafer) were used, and the pattern pitch was changed to calculate on-wafer line-width differences between the horizontal lines and the vertical lines. Since the line width of the vertical lines (VCD) is larger than the line width of the horizontal lines (HCD) because of a mask 3D effect, VCD-HCD has been plotted as an H-V bias in FIG. 15. The H-V bias depends on pitch and resulted in a maximum line-width difference of 9 nm. This line-width difference can be corrected by optical proximity correction (OPC), in which design values of the mask pattern are corrected. However, a larger correction value is undesirable because there is a possibility that the difference between calculated value and found value might increase accordingly.

FIG. 16 shows the results of the simulation of telecentricity error. Exposure was conducted by Y-direction dipole illumination under the conditions of a numerical aperture NA of 0.33, a coherent factor σ of 0.4-0.8, and an opening angle of 90 degrees. Mask patterns of the horizontal-direction L/S (line-and-space) type were used, and the patter pitch was changed from 128 nm to 320 nm (from 32 nm to 80 nm on wafer) to calculate telecentricity errors. The telecentricity errors depend on pitch and had a maximum value of 8 nm/μm. This means that in the case where the wafer is placed apart from the image formation plane, for example, by 100 nm, the pattern position shifts by 0.8 nm in a horizontal direction. In the case where this mask pattern is for forming a wiring layer, such a pattern position shift results in troubles in three-dimensional electrical connection with other wiring layers. As a result, the shift affects the yield of semiconductor integrated circuits. It is hence desirable to minimize the telecentricity errors.

### Example 2

In this Example, the reflective mask blank 10C shown in FIG. 9 is produced. The reflective mask blank 10C includes a reflective layer 12 having a phase inversion layer 12b therein. The reflective layer 12 is configured by superposing a lower multilayer film 12a, the phase inversion layer 12b, and an upper multilayer film 12c in this order from the substrate 11 side.

### (Production of Reflective Mask Blank)

This Example differs from Example 1 in the method for forming the reflective layer 12. A substrate 11, a backside electroconductive layer 16, a protective layer 13, and an absorbent layer 14 were produced by the same methods as in Example 1.

After the deposition of the backside electroconductive layer 16 on the back surface of the substrate 11, an Si film and an Mo film were alternately deposited repeatedly over 15 cycles on the front surface of the substrate 11 by ion-beam sputtering. The film thickness of each Si film was about 4.0 nm and the film thickness of each Mo film was about 3.0 nm. Thus, a lower multilayer film 12a having an overall film thickness of about 105 nm ((4.0 nm of Si film)+(3.0 nm of Mo film)×15) was formed.

The uppermost surface of the lower multilayer film 12a was an Mo film. An Si film serving as a phase inversion layer 12b was deposited thereon in a thickness of 7.5 nm. The increase in film thickness Δd of the phase inversion layer was 3.5 nm. The Δd satisfies expression (9).

Thereafter, alternate deposition of an Mo film and an Si film was repeated over 25 cycles. The film thickness of each Si film was about 4.0 nm and the film thickness of each Mo film was about 3.0 nm. Thus, an upper multilayer film 12c having an overall film thickness of about 175 nm ((4.0 nm of Si film)+(3.0 nm of Mo film)×25) was formed.

A reflective layer 12 was formed by thus depositing the lower multilayer film 12a, phase inversion layer 12b, and upper multilayer film 12c.

The total number of layers N_{ML}, of the reflective layer 12 was 81, and the number of layers Nₜₒₚ of the upper multilayer film 12c was 50.

After the deposition of the backside electroconductive layer 16 and protective layer 13, an absorbent layer 14 was deposited. The film thickness T_{abs} of the absorbent layer 14 was 61 nm (56 nm of TaN+5 nm of TaON). The N_{ML}, Nₜₒₚ, and T_{abs} satisfy expression (5).

### (Reflectance and Mask 3D Effects)

Reflectances of the reflective mask blank 10C were calculated, and the results thereof are shown in FIG. 14. The reflectances had a minimal value of 46% at a wavelength of about 13.55 nm. The reflectance at a wavelength of 13.55 nm was lower than in Example 1. This is due to the mutual attenuation of light reflected by the upper multilayer film and light reflected by the lower multilayer film.

Mask 3D effects of the reflective mask blank 10C were investigated by simulations. FIG. 15 shows the results of the simulation of H-V bias. The H-V bias had a maximum value of 4 nm, which was considerably smaller than 9 nm of Example 1.

FIG. 16 shows the results of the simulation of telecentricity error. The telecentricity errors had a maximum value of 3 nm/μm, which was considerably smaller than 8 nm/μm of Example 1.

By using the reflective mask blank 10C of this Example, the mask 3D effects can be considerably reduced.

### Example 3

In this Example, the reflective mask blank 10C shown in FIG. 9 is produced as in Example 2. This Example differs from Example 2 in the number of layers of the lower multilayer film 12a, the number of layers Nₜₒₚ of the upper multilayer film 12c, and the total number of layers N_{ML} of the reflective film 12.

### (Production of Reflective Mask Blank)

After a backside electroconductive layer 16 had been deposited on the back surface of a substrate 11, an Si film and an Mo film were alternately deposited repeatedly over 30 cycles on the front surface of the substrate 11 by ion-beam sputtering. The film thickness of each Si film was about 4.0 nm and the film thickness of each Mo film was about 3.0 nm. Thus, a lower multilayer film 12a having an overall film thickness of about 210 nm ((4.0 nm of Si film)+(3.0 nm of Mo film)×30) was formed.

The uppermost surface of the lower multilayer film 12a was an Mo film. An Si film serving as a phase inversion layer 12b was deposited thereon in a thickness of 7.5 nm. The increase in film thickness Δd of the phase inversion layer was 3.5 nm. The Δd satisfies expression (9).

Thereafter, alternate deposition of an Mo film and an Si film was repeated over 30 cycles. The film thickness of each Si film was about 4.0 nm and the film thickness of each Mo film was about 3.0 nm. Thus, an upper multilayer film 12c having an overall film thickness of about 210 nm ((4.0 nm of Si film)+(3.0 nm of Mo film)×30) was formed.

A reflective layer 12 was formed by thus depositing the lower multilayer film 12a, phase inversion layer 12b, and upper multilayer film 12c.

The total number of layers N_{ML} of the reflective layer 12 was 121, and the number of layers Nₜₒₚ of the upper multilayer film 12c was 60.

After the deposition of the backside electroconductive layer 16 and a protective layer 13, an absorbent layer 14 was deposited. The film thickness T_{abs} of the absorbent layer 14 was 61 nm. The N_{ML}, Nₜₒₚ, and T_{abs} satisfy expression (5).

### (Reflectance and Mask 3D Effects)

Reflectances were calculated and the results thereof are shown in FIG. 14. The reflectances had a minimal value of 52% at a wavelength of about 13.55 nm. The reflectance at a wavelength of 13.55 nm was lower than in Example 1 but higher than in Example 2. This is due to the larger number of layers of the upper multilayer film than in Example 2.

Mask 3D effects of the reflective mask blank 10C were investigated by simulations. FIG. 15 shows the results of the simulation of H-V bias. The H-V bias had a maximum value of 6 nm, which was smaller than 9 nm of Example 1.

FIG. 16 shows the results of the simulation of telecentricity error. The telecentricity errors had a maximum value of 4 nm/μm, which was smaller than 8 nm/μm of Example 1.

By using the reflective mask blank 10C of this Example, the mask 3D effects can be reduced while inhibiting the reflectance from decreasing.

### Example 4

In this Example, the reflective mask blank 10C shown in FIG. 9 is produced as in Example 2. This Example differs from Example 2 in the material and film thickness T_{abs} of the absorbent film 14.

### (Production of Reflective Mask Blank)

A reflective layer 12, a backside electroconductive layer 16, and a protective layer 13 were deposited in the same manners as in Example 2. The total number of layers N_{ML} of the reflective layer 12 was 81, and the number of layers Nₜₒₚ of the upper multilayer film 12c was 50.

TaSn was used as the material of the absorbent layer 14. The EUV-light refractive index and absorption coefficient of TaSn were regarded as 0.955 and 0.053, respectively. Since TaSn has a higher absorption coefficient than TaN, a reduction in film thickness can be attained.

The film thickness T_{abs} of the absorbent film 14 was set at 39 nm. The N_{ML}, Nₜₒₚ, and T_{abs} satisfy expression (5).

### (Reflectance and Mask 3D Effects)

The reflective layer 12 had the same structure as in Example 2. Hence, the reflectances are the same as in Example 2.

Mask 3D effects of the reflective mask blank 10C were investigated by simulations. FIG. 15 shows the results of the simulation of H-V bias. The H-V bias had a maximum value of 1 nm, which was smaller than 9 nm of Example 1 and than 4 nm of Example 2.

FIG. 16 shows the results of the simulation of telecentricity error. The telecentricity errors had a maximum value of 1 nm/μm, which was smaller than 8 nm/μm of Example 11.

By using the reflective mask blank 10C of this Example, in which the absorbent layer 14 has a reduced film thickness, the mask 3D effects can be further reduced.

### Example 5

### (Production of Reflective Mask Blank)

In this Example, the reflective mask blank 10C shown in FIG. 9 was produced as in Example 2. This Example differs from Example 2 in the increase in film thickness Δd of the phase inversion layer 12b. Although the Δd in Example 2 was 3.5 nm (approximately λ/4), the Δd in this Example was set at 7 nm (approximately λ/2). This Δd does not satisfy expression (7). In this Example, light reflected by the upper multilayer film 12c and light reflected by the lower multilayer film 12a were equal in phase. These conditions are the same as in Patent Document 2.

### (Reflectance and Mask 3D Effects)

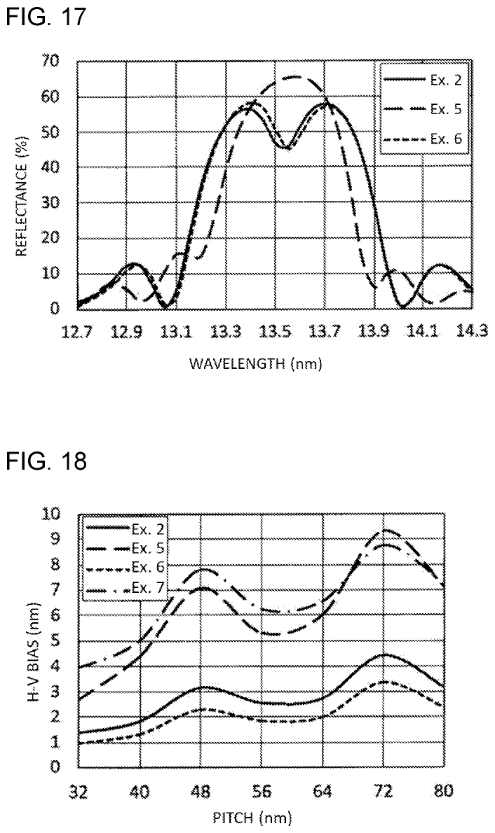

Reflectances were calculated and the results thereof are shown in FIG. 17. The reflectances had a maximum value of 66% at a wavelength of about 13.55 nm as in Example 1.

FIG. 18 shows the results of a simulation of H-V bias. The H-V bias had a maximum value of 9 nm as in Example 1.

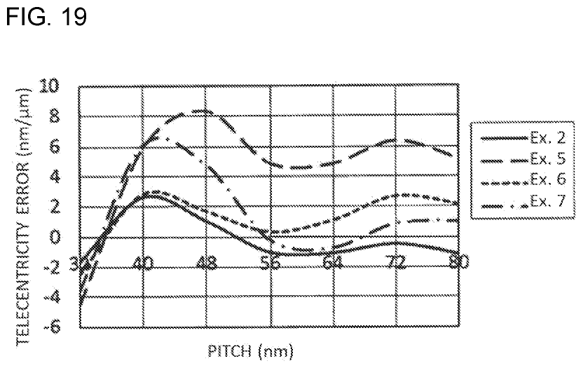

FIG. 19 shows the results of a simulation of telecentricity errors. The telecentricity errors had a maximum value of 8 nm/μm as in Example 1.

The reflective mask blank 10C of this Example cannot be used to reduce the mask 3D effects.

### Example 6

### (Production of Reflective Mask Blank)

In this Example, the reflective mask blank 10C shown in FIG. 9 was produced as in Example 2. This Example differs from Example 2 in the increase in film thickness Δd of the phase inversion layer 12b. Although the Δd in Example 2 was 3.5 nm (approximately λ/4), the Δd in this Example was set at 10.5 nm (approximately 3λ/4). This Δd satisfies expression (7).

### (Reflectance and Mask 3D Effects)

Reflectances were calculated and the results thereof are shown in FIG. 17. The reflectances had a minimal value at a wavelength of about 13.55 nm as in Example 2.

FIG. 18 shows the results of a simulation of H-V bias. The H-V bias had a maximum value of 3 nm, which was slightly smaller than in Example 2.

FIG. 19 shows the results of a simulation of telecentricity errors. The telecentricity errors had a maximum value as small as 3 nm/μm as in Example 2.

By using the reflective mask blank 10C of this Example, the mask 3D effects can be reduced.

### Example 7

### (Production of Reflective Mask Blank)

In this Example, the reflective mask blank 10C shown in FIG. 9 was produced as in Example 2. This Example differs from Example 2 in the film thickness of the absorbent layer 14. In Example 2, the film thickness T_{abs} of the absorbent layer 14 was 61 nm (56 nm of TaN+5 nm of TaON). In this Example, the T_{abs} was increased to 90 nm (85 nm of TaN+5 nm of TaON). In this Example, the total number of layers N_{ML}, of the reflective layer 12 was 81 and the number of layers Nₜₒₚ of the upper multilayer film 12c was 50, which were the same as in Example 2. The N_{ML}, Nₜₒₚ, and T_{abs} do not satisfy expression (5).

### (Reflectance and Mask 3D Effects)

The reflective layer 12 had the same structure as in Example 2. Hence, the reflectances are the same as in Example 2.

FIG. 18 shows the results of a simulation of H-V bias. The H-V bias had a maximum value as large as 9 nm as in Example 1.

FIG. 19 shows the results of a simulation of telecentricity errors. The telecentricity errors had a maximum value of 6 nm/μm, which was slightly smaller than 8 nm/μm of Example 1 but far larger than 3 nm/μm of Example 2.

The reflective mask blank 10C of this Example cannot be used to reduce the mask 3D effects. In this Example, the reflective layer 12 had a reflection plane therein in a shallowed position but the effect thereof was eliminated by the increased film thickness of the absorbent layer 14.

Although embodiments are explained above, the embodiments are mere examples and the present invention is not limited by the embodiments. The embodiments can be practiced in various other modes, and within the gist of the present invention, various combinations, omissions, replacement, modifications, etc. are possible. The embodiments and modifications thereof are included in the scope and gist of the present invention and in ranges equivalent to the invention described in the claims.

### REFERENCE SIGNS LIST

10A, 10B, 10C, 10D Reflective mask blank
11 Substrate
11a First main surface
11b Second main surface
12 Reflective layer
12a Lower multilayer film
12b Phase inversion layer
12c Upper multilayer film
13 Protective layer
14 Absorbent layer
15 Hard mask layer
16 Backside electroconductive layer
18 Resist layer
20 Reflective mask
141 Absorber pattern
181 Resist pattern

1. A reflective mask blank comprising a substrate and, disposed on or above the substrate in the following order from the substrate side, a reflective layer for reflecting EUV light, a protective layer, and an absorbent layer for absorbing EUV light,
wherein the reflective layer is a multilayered reflective film comprising a plurality of cycles, each cycle including a high-refractive-index layer and a low-refractive-index layer,
wherein the reflective layer comprises one phase inversion layer which is either the high-refractive-index layer or the low-refractive-index layer each having a film thickness increased by Δd ([unit: nm]),
wherein the increase in film thickness Δd [unit: nm] of the phase inversion layer satisfies a relationship:
(¼+m/2)×13.53−1.0≤Δd≤(¼+m/2)×13.53+1.0
where m is an integer of 0 or larger, and
wherein the reflective layer and the absorbent layer satisfy a relationship:
T_{abs}+80 tanh(0.037N_{ML})−1.6 exp(−0.08Nₜₒₚ)(N_{ML}−Nₜₒₚ)²<140
where N_{ML} is the total number of layers of the reflective layer, Nₜₒₚ is the number of layers of an upper multilayer film that is a portion of the reflective layer which overlies the phase inversion layer, and T_{abs} [unit: nm] is a film thickness of the absorbent layer.

2. The reflective mask blank according to claim 1,
wherein a material of the high-refractive-index layer comprises Si, and a material of the low-refractive-index layer comprises at least one metal selected from the group consisting of Mo and Ru.

3. The reflective mask blank according to claim 1,
wherein a material of the high-refractive-index layer is Si, and a material of the low-refractive-index layer is Mo,
wherein a cycle length is in a range of 6.5 to 7.5 nm, and
wherein ΓMo ([thickness of Mo layer]/[cycle length]) is in a range of 0.25 to 0.7.

4. The reflective mask blank according to claim 1, comprising a buffer layer having a film thickness of 1 nm or less disposed between the low-refractive-index layer and the high-refractive-index layer.

5. The reflective mask blank according to claim 4,
wherein a material of the buffer layer is B₄C.

6. The reflective mask blank according to claim 1, wherein the number of layers Nₜₒₚ of the upper multilayer film is 20 or more and 100 or less.

7. The reflective mask blank according to claim 1, comprising a hard mask layer on the absorbent layer.

8. The reflective mask blank according to claim 7,
wherein the hard mask layer comprises at least one element selected from the group consisting of Cr and Si.

9. The reflective mask blank according to claim 1, comprising a backside electroconductive layer on a back surface of the substrate.

10. The reflective mask blank according to claim 9,
wherein a material of the backside electroconductive layer is Cr or Ta or an alloy or compound of either.

11. A reflective mask obtained by forming a pattern in the absorbent layer of the reflective mask blank according to claim 1.

12. A process for producing a reflective mask blank comprising a substrate and, disposed on or above the substrate in the following order from the substrate side, a reflective layer for reflecting EUV light, a protective layer, and an absorbent layer for absorbing EUV light,
the reflective layer being a multilayered reflective film comprising a plurality of cycles, each cycle being composed of a high-refractive-index layer and a low-refractive-index layer,
the reflective layer comprising a lower multilayer film, a phase inversion layer which is either the high-refractive-index layer or the low-refractive-index layer each having an increased film thickness, and an upper multilayer film which have been superposed in this order from the substrate side, the process comprising:
forming the lower multilayer film on the substrate;
forming the phase inversion layer on the lower multilayer film;
forming the upper multilayer film on the phase inversion layer;
forming the protective film on the upper multilayer film, and
forming the absorbent layer on the protective layer.
